(19) United States
(12) Patent Application Publication
(10) Pub. No.: US 2025/0267950 A1
(43) Pub. Date: Aug. 21, 2025

(54) Electronic device

(71) Applicant: InnoLux Corporation, Miao-Li County (TW)

(72) Inventors: Tsan-Chu LU, Miao-Li County (TW); Shih-Siang YAN, Miao-Li County (TW); Shu-Wei HSU, Miao-Li County (TW)

(21) Appl. No.: 19/027,628

(22) Filed: Jan. 17, 2025

(30) Foreign Application Priority Data
Feb. 19, 2024 (CN) 202410183304.X

(51) Int. Cl. H10D 89/60; G01R 31/00; G01R 31/28

(52) U.S. Cl. CPC H10D 89/60; G01R 31/002; G01R 31/2884

(57) ABSTRACT

An electronic device includes: a substrate including a work area and a peripheral area, wherein the peripheral area surrounds the work area; a test terminal disposed on the peripheral area; and an electrostatic protection structure disposed on the peripheral area; wherein in a top view direction, the electrostatic protection structure is located between the test terminal and an edge of the substrate.

### CROSS-REFERENCE TO RELATED APPLICATIONS

This application claims the benefits of the Chinese Patent Application Serial Number 202410183304.X, filed on Feb. 19, 2024, the subject matter of which is incorporated herein by reference.

### BACKGROUND

### Field

The present disclosure provides an electronic device and, more particularly to an electronic device comprising a test terminal.

### Description of Related Art

With the advancement of electronic device technology, the electronic components used in electronic devices are becoming more and more precise and in increasing numbers, resulting in problems such as damage to electronic components or failure of electronic devices due to electrostatic discharge. Therefore, when the electronic device is completed, the electronic device is usually tested for electrostatic discharge (ESD) test to confirm the electrostatic protection capability of the electronic device.

However, the current generated in the electrostatic discharge test may cause damage to the electronic components in the electronic device, causing the production yield of the electronic device to decrease, thereby affecting production costs.

Therefore, it is desirable to provide an electronic device to improve the aforesaid shortcomings.

### SUMMARY

The present disclosure provides an electronic device, comprising: a substrate comprising a work area and a peripheral area, wherein the peripheral area surrounds the work area; a test terminal disposed on the peripheral area; and an electrostatic protection structure disposed on the peripheral area, wherein the electrostatic protection structure is located between the test terminal and an edge of the substrate in a top view direction.

Other novel features of the disclosure will become more apparent from the following detailed description when taken in conjunction with the accompanying drawings.

### BRIEF DESCRIPTION OF DRAWINGS

FIG. 1A is a top schematic diagram of an electronic device according to one embodiment of the present invention.

FIG. 1B is a partial enlarged diagram of FIG. 1A.

FIG. 2A is a top schematic diagram of a part of an electronic device according to one embodiment of the present invention.

FIG. 2B is a cross-sectional schematic diagram of FIG. 2A along the line A-A′.

FIG. 2C is a cross-sectional schematic diagram of FIG. 2A along the line B-B′.

FIG. 2D is a cross-sectional schematic diagram of FIG. 2A along the line C-C′.

FIG. 3 is a top schematic diagram of a part of an electronic device according to one embodiment of the present invention.

FIG. 4A is a top schematic diagram of a part of an electronic device according to one embodiment of the present invention.

FIG. 4B is a cross-sectional schematic diagram of FIG. 4A along the line D-D′.

FIG. 4C is a cross-sectional schematic diagram of FIG. 4A along the line E-E′.

FIG. 4D is an enlarged view of the dash line portion of FIG. 4A.

FIG. 5A is a top schematic diagram of a part of an electronic device according to one embodiment of the present invention.

FIG. 5B is a cross-sectional schematic diagram of FIG. 5A along the line F-F′.

FIG. 5C is an enlarged view of the dash line portion of FIG. 5A.

### DETAILED DESCRIPTION

The following is a detailed description of the electronic device according to embodiments of the present disclosure. It should be understood that the following description provides many different embodiments for implementing different aspects of some embodiments of the present disclosure. The specific components and arrangements described below are merely used to briefly and clearly describe some embodiments of the present disclosure. Of course, these are only examples and not limitations of the present disclosure. Furthermore, similar and/or corresponding reference numbers may be used to identify similar and/or corresponding elements in different embodiments to clearly describe the present disclosure. However, the use of these similar and/or corresponding reference numerals is only for the purpose of simply and clearly describing some embodiments of the present disclosure, and does not imply any correlation between the different embodiments and/or structures discussed.

It should be understood that relative terms, such as “lower” or “bottom” or “higher” or “top” may be used in the embodiments to describe the relative relationship of one element to another element shown in the drawings. It will be understood that if the device in the drawings is turned upside down, elements described as being on the “lower” side would then be elements described as being on the “higher” side. The embodiments of the present disclosure can be understood together with the drawings, and the drawings of the present disclosure are also regarded as part of the disclosure description. It is to be understood that the drawings of the present disclosure are not drawn to scale and, in fact, the dimensions of elements may be arbitrarily enlarged or reduced in order to clearly illustrate features of the present disclosure.

When a structure (or layer, component, or substrate) described in the present disclosure is located on/above another structure (or layer, component, or substrate), it may mean that the two structures are adjacent and directly connected, or the two structures are adjacent and indirectly connected. Indirect connection means that there is at least one intermediary structure (or intermediary layer, intermediary component, intermediary substrate, intermediary spacer) between two structures. The lower surface of one structure is adjacent to or directly connected to the upper surface of the intermediary structure, and the upper surface of another structure is adjacent to or directly connected to the lower surface of the intermediate structure. The intermediary structure can be composed of a single-layer or multi-layer physical structure or non-physical structure, and is not limited. In the present disclosure, when a structure is disposed “on” another structure, it may mean that the structure is “directly” on the other structure, or the structure is “indirectly” on the other structure, that is, at least one structure is sandwiched between the certain structure and the other structure.

It should be noted that, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation. The claims and the description may not use the same terms. For example, a first element in the description may be a second element in the claims.

In some embodiments of the present disclosure, terms related to joining and connecting, such as “connection”, “interconnection”, etc., unless otherwise defined, may mean that two structures are in direct contact, or may also mean that the two structures are not in direct contact where other structures are located between the two structures. The terms “joint” and “connected” can also include situations where both structures are movable, or where both structures are fixed. In addition, the terms “electrical connection” or “coupling” include any direct and indirect means of electrical connection.

In the present disclosure, the terms, such as “about”, “substantially”, or “approximately”, are generally interpreted as within 10%, 5%, 3%, 2%, 1%, or 0.5% of a given value or range. Unless otherwise stated, the term “ranging between a first value and a second value” means that the range includes the first value, the second value, and other values therebetween. In addition, any two values or directions used for comparison may have certain errors. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°. In the present disclosure, the terms “a given range is a first value to a second value” and “a given range falls within the range of a first value to a second value” mean that the given range includes the first value, the second value, and other values therebetween.

Furthermore, according to embodiments of the present disclosure, optical microscopy (OM), scanning electron microscope (SEM), film thickness profiler (α-step), ellipsometer, or other suitable methods may be to measure the thickness, length and width of each component or the distance and angle between components. Specifically, according to some embodiments, a scanning electron microscope can be used to obtain cross-sectional images of the structure, and measure the thickness, length and width of each component, or the distance and angle between components.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

It should be noted that the features provided in different embodiments below can be replaced, combined or mixed with each other to constitute another embodiment without violating the spirit of the present disclosure. The features of various embodiments may be combined and used in any combination as long as they do not violate the spirit of the invention or conflict with each other.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way. The present disclosure can be understood by referring to the following detailed description in combination with the accompanying drawings. It should be noted that, in order to make it easy for readers to understand and for the simplicity of the drawings, the multiple drawings in the present disclosure only depict a part of the electronic device, and certain elements in the drawings are not drawn to actual scale. In addition, the number and size of each element in the figures are only for illustration and are not intended to limit the scope of the present disclosure.

The electronic device of the present disclosure may include an electronic component, which may comprise a passive component, an active component or a combination thereof, such as a capacitor, a resistor, an inductor, a varactor diode, a variable capacitor, a filter, a diode, a transistor, a sensor, a microelectromechanical system (MEMS), or a liquid crystal chip; but the present disclosure is not limited thereto. The diode may include a light emitting diode or a non-light emitting diode. The diode may include a P-N junction diode, a PIN diode or a constant current diode. The light emitting diode may comprise, for example, an organic light emitting diode (OLED), a mini light emitting diode (mini LED), a micro light emitting diode (micro LED), a quantum dot light emitting diode (quantum dot LED), fluorescence, phosphors, other suitable material or a combination thereof; but the present disclosure is not limited thereto. The sensor may comprise, for example, a capacitive sensor, an optical sensor, an electromagnetic sensor, a fingerprint sensor (FPS), a touch sensor, an antenna or a pen sensor; but the present disclosure is not limited thereto. The present disclosure will be explained below by taking a display device as an electronic device; but the present disclosure is not limited thereto.

The electronic device may comprise an image capturing device, a laminating device, a display device, a backlight device, an antenna device, a tiled device, a touch electronic device (touch display), a curved electronic device (curved display) or a free shape electronic device (free shape display); but the present disclosure is not limited thereto. The electronic device may comprise, for example, liquid crystals, light emitting diodes, fluorescence, phosphors, other suitable display medium or a combination thereof; but the present disclosure is not limited thereto. The display device may be a non-self-luminous display device or a self-luminous display device; the antenna device may be a liquid crystal type antenna device or a non-liquid crystal type antenna device; the sensing device may be a sensing device that senses capacitance, light, heat energy or ultrasonic waves; but the present disclosure is not limited thereto. The tiled device may be, for example, a tiled display device or a tiled antenna device; but the present disclosure is not limited thereto. It should be noted that the electronic device may be any combination of the above; but the present disclosure is not limited thereto. The electronic device may be a bendable or flexible electronic device. It should be noted that the electronic device may be nay combination of the above; but the present disclosure is not limited thereto. In addition, the shape of the electronic device may be a rectangle, a circle, a polygon, a shape with curved edges, or other suitable shapes. The electronic device can have peripheral systems such as drive system, control system, light source system, shelf system, etc. to support display devices, antenna devices or tiled devices. It should be noted that the features provided in different embodiments below can be replaced, combined or mixed with each other to constitute another embodiment without violating the spirit of the present disclosure. Features in various embodiments may be mixed and matched as long as they do not violate the spirit of the invention or conflict with each other. It should be noted that the technical solutions provided in different embodiments below can be replaced, combined or mixed with each other to constitute another embodiment without violating the spirit of the present disclosure.

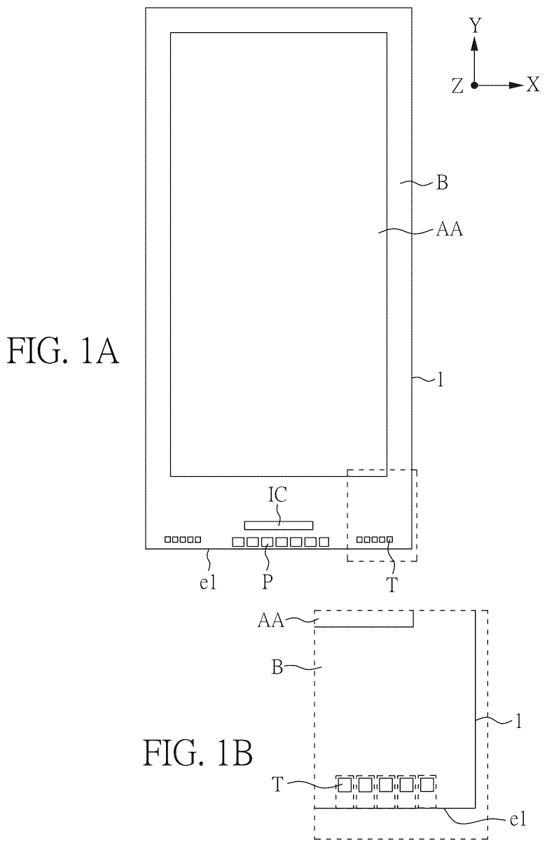

FIG. 1A is a top schematic diagram of an electronic device according to one embodiment of the present invention. FIG. 1B is a partial enlarged diagram of FIG. 1A.

In one embodiment of the present invention, as shown in FIG. 1A and FIG. 1B, the electronic device may comprise: a substrate 1 comprising a work area AA and a peripheral area B, wherein the peripheral area B surrounds the work area AA, the work area AA may be, for example, an active area or a display area, and the peripheral area B may be, for example, a non-active area or a non-display area; and a test terminal T disposed on the peripheral area B. In the present disclosure, the test terminal T may be electrically connected to the work area AA through a conductive line (not shown in the figure) and so on. Thus, the test terminal T may be used to, for example, perform an electrostatic discharge (ESD) test on the electronic device during or after the electronic device is made to confirm the electrostatic protection capability of the electronic device, or perform an electrical testing during or after the electronic device is made to improve product reliability.

In one embodiment of the present invention, as shown in FIG. 1A, the electronic device may further comprise: a plurality of pads P disposed on the peripheral area B; and an integrated circuit IC disposed on the peripheral area B, wherein the pads P are electrically connected to the integrated circuit IC. In the present disclosure, the pads P may be electrically connected to a circuit board (not shown in the figure), and the integrated circuit IC may be electrically connected to the work area AA through a conductive line (not shown in the figure), etc. Thus, the circuit board (not shown in the figure) may transmit signals (for example, scan signals, data signals or a combination thereof) to the work area AA of the electronic device through the pads P and the integrated circuit IC, to drive the electronic device. In one embodiment of the present invention, as shown in FIG. 1A, in a top view direction Z of the electronic device, the pads P may be disposed between the integrated circuit IC and an edge e1 of the substrate 1.

In the present disclosure, the material of the substrate 1 may be glass, quartz, sapphire, ceramics, plastic, polycarbonate (PC), polyimide (PI), polypropylene (PP), polyethylene terephthalate (PET), polymethylmethacrylate (PMMA), other suitable materials or a combination thereof; but the present disclosure is not limited thereto. In the present disclosure, the same or different materials may be used to prepare the plurality of pads P, and the materials of the pads P may respectively comprise gold, silver, copper, aluminum, titanium, chromium, nickel, molybdenum, tungsten, indium tin oxide (ITO), indium zinc oxide (IZO), indium tin zinc oxide (ITZO), indium gallium zinc oxide (IGZO) or a combination thereof; but the present disclosure is not limited thereto. In the present disclosure, the circuit board (not shown in the figure) may be a rigid circuit board or a flexible circuit board, such as a printed circuit board (PCB) or a flexible printed circuit (FPC); but the present disclosure is not limited thereto.

In one embodiment of the present invention, even not shown in the figure, the electronic device may comprise a display medium layer, and suitable material for the display medium layer may comprise guest host type liquid crystal (GHLC), dye liquid crystal, twisted nematic liquid crystal (TN LC), super twisted nematic liquid crystal (STN LC), polymer dispersed liquid crystal (PDLC), polymer network liquid crystal (PNLC), cholesteric texture liquid crystal, polymer-stabilized cholesteric texture liquid crystal (PSCT LC), suspended particle material (SPD), electrochromic material, microcapsule, microcup, quick-response liquid powder display (QR-LPD) or a combination thereof; but the present disclosure is not limited thereto. In one embodiment of the present invention, even not shown in the figure, the electronic device may comprise a counter substrate disposed opposite to the substrate 1, wherein the material of the counter substrate may be similar to that of the substrate 1, and is not described again here. In one embodiment of the present invention, the electronic device may be a display device; but the present disclosure is not limited thereto.

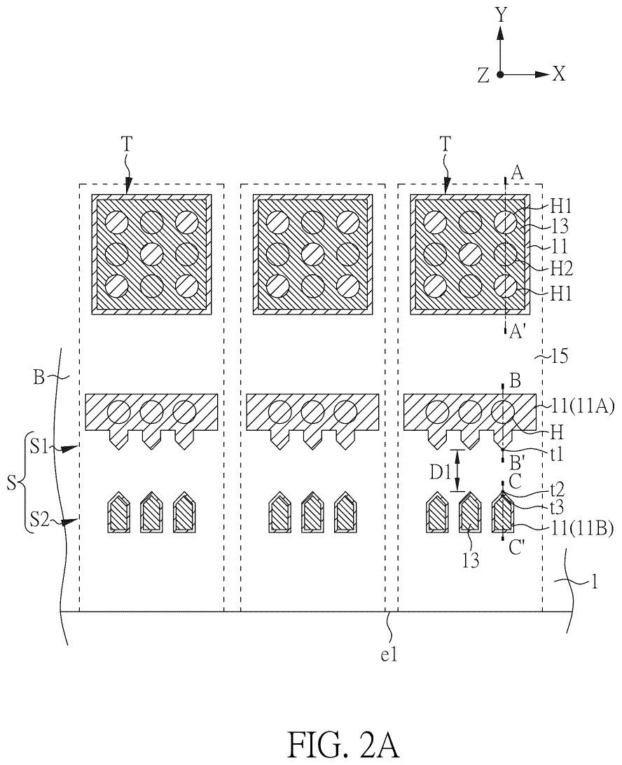

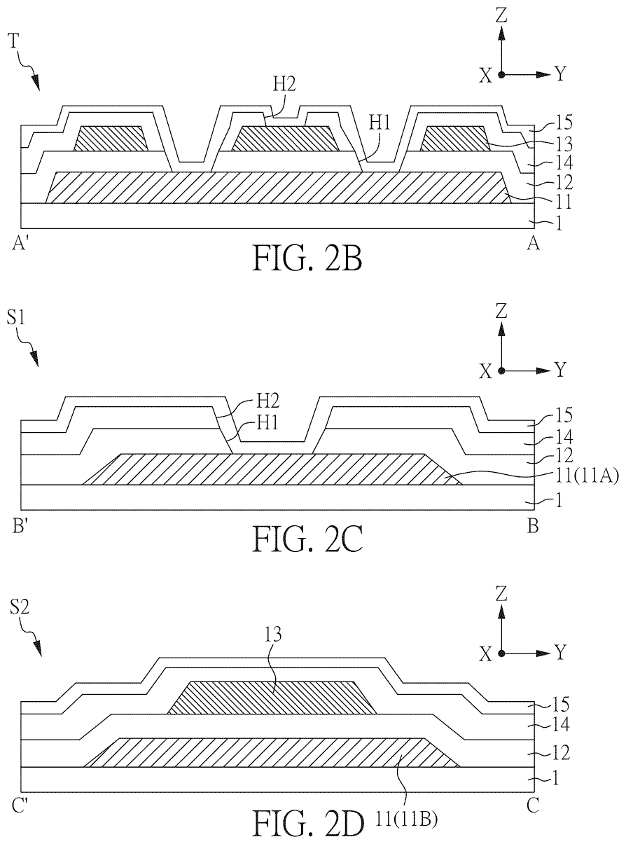

FIG. 2A is a top schematic diagram of a part of an electronic device according to one embodiment of the present invention. FIG. 2A may be, for example, a partial enlarged diagram of FIG. 1B. FIG. 2B is a cross-sectional schematic diagram of FIG. 2A along the line A-A′. FIG. 2C is a cross-sectional schematic diagram of FIG. 2A along the line B-B′. FIG. 2D is a cross-sectional schematic diagram of FIG. 2A along the line C-C′. For convenience of explanation, some components are omitted in FIG. 2A.

In one embodiment of the present invention, as shown in FIG. 2A, the electronic device may comprise: a test terminal T disposed on the peripheral area B; and an electrostatic protection structure S disposed on the peripheral area B, wherein the electrostatic protection structure S is located between the test terminal T and an edge e1 of the substrate 1 in a top view direction Z of the electronic device. In one embodiment of the present invention, the electrostatic protection structure S is electrically connected to the test terminal T. When a voltage is applied externally to the electronic device for electrostatic discharge test, the current generated by the electrostatic discharge test will first pass through the electrostatic protection structure S, and then enter the work area AA (as shown in FIG. 1A) of the electronic device through the test terminal T that is electrically connected to the electrostatic protection structure S to perform the electrostatic discharge test. In the present disclosure, the electrostatic protection structure S can be used to provide electrostatic discharge or prevent the current generated during electrostatic discharge test from directly impacting the electronic components in the work area AA (as shown in FIG. 1A), thereby improving the reliability of the electronic device.

In one embodiment of the present invention, as shown in FIG. 2A and FIG. 2B, the test terminal T may comprise: a first metal layer 11 disposed on the substrate 1; a first insulating layer 12 disposed on the first metal layer 11; a second metal layer 13 disposed on the first insulating layer 12; a second insulating layer 14 disposed on the second metal layer 13; and a conductive layer 15 disposed on the second insulating layer 14, wherein the conductive layer 15 is electrically connected to the first metal layer 11 and the second metal layer 13. More specifically, the conductive layer 15 may be electrically connected to the first metal layer 11 through an opening H1 of the first insulating layer 12, and the conductive layer 15 may be electrically connected to the second metal layer 13 through an opening H2 of the second insulating layer 14. In the present disclosure, even not shown in the figure, the first metal layer 11 and the second metal layer 13 may be electrically connected to the work area AA (as shown in FIG. 1A) respectively. Thus, the test terminal T may transmit signals to the work area AA (as shown in FIG. 1A) through the conductive layer 15, the first metal layer 11 and the second metal layer 13 to achieve the purpose of electrostatic discharge test.

In one embodiment of the present invention, as shown in FIG. 2A, FIG. 2C and FIG. 2D, the electrostatic protection structure S may comprise: a first portion S1 and a second portion S2, wherein the second portion S2 of the electrostatic protection structure S is located between the first portion S1 of the electrostatic protection structure S and the edge e1 of the substrate 1 in the top view direction Z. In one embodiment of the present invention, as shown in FIG. 2A and FIG. 2C, the first portion S1 of the electrostatic protection structure S may comprise: a first metal layer 11 disposed on the substrate 1; a first insulating layer 12 disposed on the first metal layer 11; a second insulating layer 14 disposed on the first insulating layer 12; and a conductive layer 15 disposed on the first insulating layer 12 and the second insulating layer 14, wherein the conductive layer 15 is electrically connected to the first metal layer 11, and the conductive layer 15 is electrically connected to the test terminal T. In one embodiment of the present invention, as shown in FIG. 2A and FIG. 2D, the second portion S2 of the electrostatic protection structure S may comprise: a first metal layer 11 disposed on the substrate 1; a first insulating layer 12 disposed on the first metal layer 11; a second metal layer 13 disposed on the first insulating layer 12; a second insulating layer 14 disposed on the second metal layer 13; and a conductive layer 15 disposed on the first insulating layer 12 and the second insulating layer 14, wherein the conductive layer 15 is electrically connected to the first portion S1 of the electrostatic protection structure S.

In one embodiment of the present invention, as shown in FIG. 2A, FIG. 2C and FIG. 2D, the first metal layer 11 may comprise a first metal portion 11A and a second metal portion 11B, the first metal portion 11A is electrically connected to the conductive layer 15, and the second metal portion 11B is electrically insulated from the conductive layer 15. More specifically, as shown in FIG. 2A and FIG. 2C, the conductive layer 15 may be electrically connected to the first metal portion 11A through an opening H (for example, the opening H1 of the first insulating layer 12 and the opening H2 of the second insulating layer 14) of the insulating layer.

In one embodiment of the present invention, as shown in FIG. 2A, in the top view direction Z of the electronic device, the first metal portion 11A comprises a first tip t1, the second metal portion 11B comprises a second tip t2, and the first tip t1 is disposed opposite to the second tip t2. When performing an electrostatic discharge test on the electronic device, the current can be directed to the first metal portion 11A through the conductive layer 15, the tip discharge is performed on the second tip t2 of the second metal portion 11B through the first tip t1 of the first metal portion 11A, so that the current is discharged or released here, thereby preventing the generated current from directly impacting the electronic components in the work area AA (as shown in FIG. 1A). In one embodiment of the present invention, there is a first distance D1 between the first tip t1 and the second tip t2, and the first distance D1 is greater than or equal to 2 μm and less than or equal to 10000 μm. That is, the first distance D1 may range from 2 μm to 10000 μm (2 μm≤D1≤10000 μm), for example, the first distance D1 may range from 2 μm to 8000 μm, from 2 μm to 5000 μm, from 2 μm to 3000 μm or from 2 μm to 1000 μm; but the present disclosure is not limited thereto. The measurement method of the first distance D1 may, for example, use the aforementioned optical microscopy (OM), scanning electron microscope (SEM) and other measurement tools to measure the minimum distance between the first tip t1 and the second tip t2 along an extension direction thereof in the top view of the electronic device.

In one embodiment of the present invention, as shown in FIG. 2A, in the top view direction Z of the electronic device, the second metal layer 13 may comprise a third tip t3 disposed opposite to the first tip t1. When performing an electrostatic discharge test on the electronic device, part of the current can be tip-discharged on the third tip t3 of the second metal layer 13 through the first tip t1 of the first metal portion 11A, causing the current to discharge or release, which can reduce damage to the electronic device. Herein, “the first tip is disposed opposite to the second tip/third tip” means, for example, that the protruding direction of the first tip t1 is opposite to the protruding direction of the second tip t2/third tip t3 (for example, the protruding direction of the first tip t1 is toward the edge e1 of the substrate 1, and the protruding direction of the second tip t2/third tip t3 is away from the edge e1 of the substrate 1), or means, for example, the vertex of the first tip t1 is opposite to the vertex of the second tip t2/third tip t3.

In one embodiment of the present invention, as shown in FIG. 2A to FIG. 2D, a suitable method may be used to form a metal layer on the substrate 1, followed by patterning the metal layer through lithography to respectively form the first metal layer 11 of the test terminal T and the electrostatic protection structure S. Next, a suitable method may be used to form a first insulating layer 12 on the first metal layer 11. Then, a suitable method may be used to form another metal layer on the first insulating layer 12, followed by patterning the metal layer through lithography to respectively form the second metal layer 13 of the test terminal T and the electrostatic protection structure S. Next, a suitable method is used to form a second insulating layer 14 on the second metal layer 13. Then, a suitable method is used to form a conductive material on the second insulating layer 14, followed by patterning the conductive material through lithography to respectively form the conductive layer 15 of the test terminal T and the electrostatic protection structure S. Herein, suitable method may include electroplating, chemical plating, chemical vapor deposition, sputtering, coating or a combination thereof; but the present disclosure is not limited thereto. The “coating” may be, for example, dip coating, spin coating, roller coating, blade coating, spray coating or a combination thereof; but the present disclosure is not limited thereto. In one embodiment of the present invention, as shown in FIG. 2A, the conductive layer 15 may be disposed extending from the edge e1 of the substrate 1, thereby forming the conductive layer 15 of the test terminal T and the electrostatic protection structure S.

In the present disclosure, the same or different materials may be used to prepare the first metal layer 11 and the second metal layer 13, and the materials of the first metal layer 11 and the second metal layer 13 may respectively comprise, for example, gold, silver, copper, palladium, platinum, ruthenium, aluminum, cobalt, nickel, titanium, molybdenum, manganese, an alloy thereof or a combination thereof; but the present disclosure is not limited thereto. In the present disclosure, the same or different materials may be used to prepare the first insulating layer 12 and the second insulating layer 14, and the material of the first insulating layer 12 and the second insulating layer 14 may respectively comprise, for example, silicon nitride, silicon oxide, silicon oxynitride, silicon carbonitride, aluminum oxide, resin, polymer, photoresist or a combination thereof; but the present disclosure is not limited thereto. In the present disclosure, the material of the conductive layer 15 may comprise a metal oxide, such as indium zinc oxide (IZO), indium tin oxide (ITO), indium tin zinc oxide (ITZO), indium gallium zinc oxide (IGZO), or aluminum zinc oxide (AZO); but the present disclosure is not limited thereto.

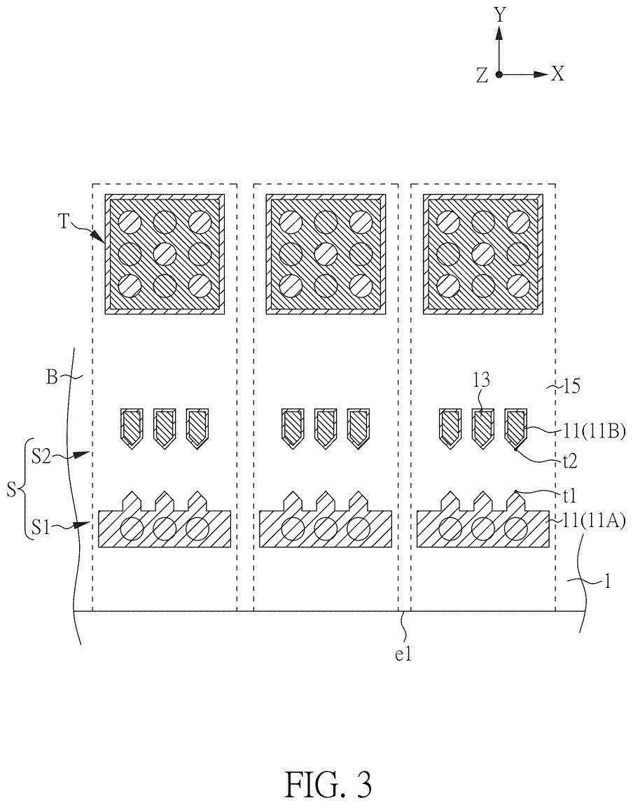

FIG. 3 is a top schematic diagram of a part of an electronic device according to one embodiment of the present invention. The electronic device in FIG. 3 is similar to that in FIG. 2A, except for the following differences. For convenience of explanation, some components are omitted in FIG. 3.

In one embodiment of the present invention, as shown in FIG. 3, the electronic device may comprise: a test terminal T disposed on the peripheral area B; and an electrostatic protection structure S disposed on the peripheral area B. The electrostatic protection structure S may comprise a first portion S1 and a second portion S2, wherein the first portion S1 of the electrostatic protection structure S is located between the second portion S2 of the electrostatic protection structure S and the edge e1 of the substrate 1 in the top view direction Z.

In the present disclosure, the cross-section of the test terminal T in FIG. 3 may be shown as FIG. 2B, the cross-section of the first portion S1 of the electrostatic protection structure S in FIG. 3 may be shown as FIG. 2C, and the cross-section of the second portion S2 of the electrostatic protection structure S in FIG. 3 may be shown as FIG. 2D, which are not described here again. Thus, when performing an electrostatic discharge test on the electronic device, the current can be transmitted to the first metal portion 11A through the conductive layer 15, and performs tip discharge on the second tip t2 of the second metal portion 11B through the first tip t1 of the first metal portion 11A. Thus, the current can be discharged or released here to avoid the current from directly impacting the electronic components in the work area AA (as shown in FIG. 1). In one embodiment of the present invention, the protruding direction of the first tip t1 is away from the edge e1 of substrate 1, and the protruding direction of the second tip t2 is towards the edge e1 of substrate 1.

In the present disclosure, other details of the test terminal T and the electrostatic protection structure S may be as described above and are not described here again. In addition, the materials and the manufacturing processes of the first metal layer 11, the second metal layer 13, the first insulating layer 12, the second insulating layer 14 and the conductive layer 15 may also refer to those described above and are not described here again.

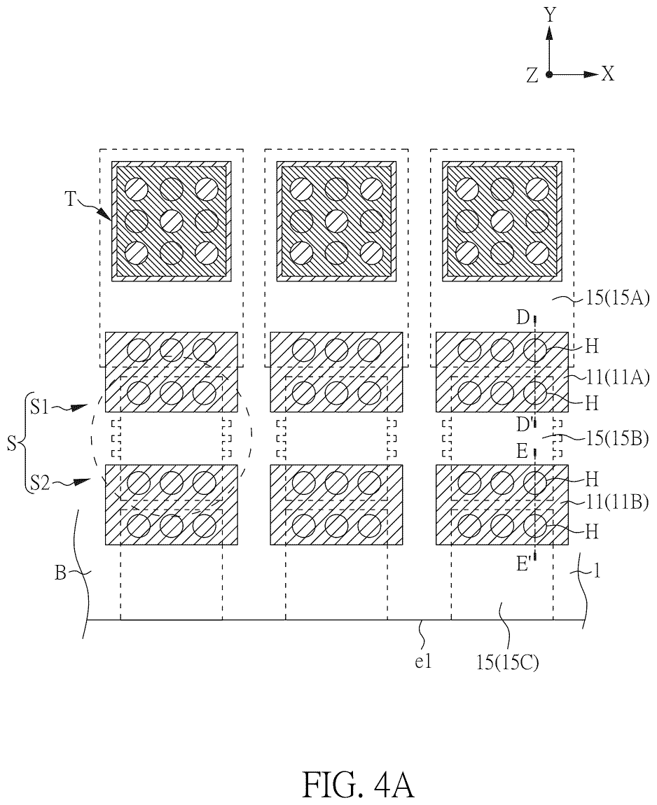

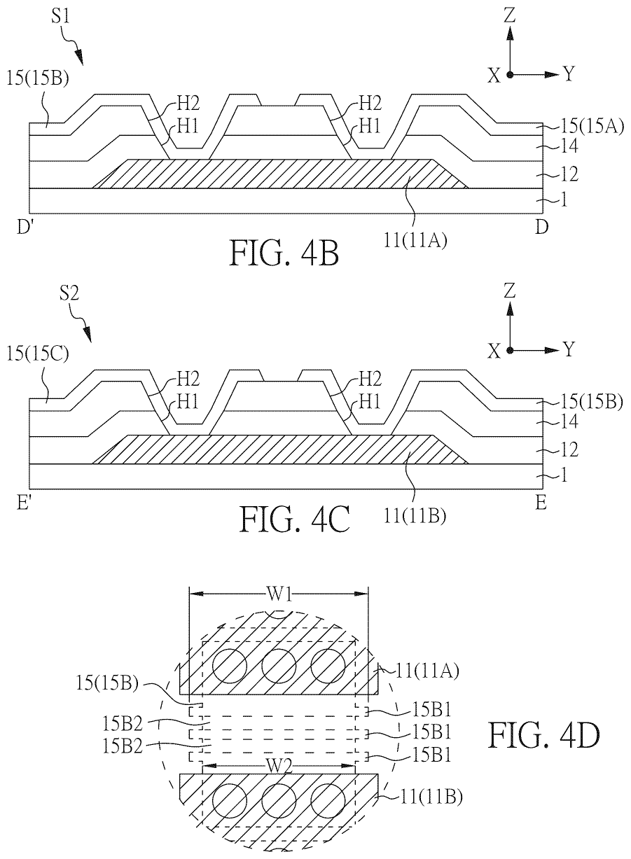

FIG. 4A is a top schematic diagram of a part of an electronic device according to one embodiment of the present invention. FIG. 4B is a cross-sectional schematic diagram of FIG. 4A along the line D-D′. FIG. 4C is a cross-sectional schematic diagram of FIG. 4A along the line E-E′. FIG. 4D is an enlarged view of the dash line portion of FIG. 4A. For convenience of explanation, some components are omitted in FIG. 4A and FIG. 4D.

In one embodiment of the present invention, as shown in FIG. 4A, the electronic device may comprise: a test terminal T disposed on the peripheral area B; and an electrostatic protection structure S disposed on the peripheral area B, wherein the electrostatic protection structure S is located between the test terminal T and the edge e1 of the substrate 1 in the top view direction Z of the electronic device. In the present disclosure, the test terminal T in FIG. 4A is the same as the test terminal T in FIG. 2A, so the cross-section of the test terminal T in FIG. 4A may be as shown in FIG. 2B and is not described here again.

In one embodiment of the present invention, as shown in FIG. 4A to FIG. 4C, the electrostatic protection structure S may comprise: a first metal layer 11 disposed on the substrate 1; a first insulating layer 12 disposed on the first metal layer 11; a second insulating layer 14 disposed on the first insulating layer 12; and a conductive layer 15 disposed on the first insulating layer 12 and the second insulating layer 14, wherein the conductive layer 15 is electrically connected to the first metal layer 11, and the conductive layer 15 is electrically connected to the test terminal T.

In one embodiment of the present invention, as shown in FIG. 4A to FIG. 4C, the first metal layer 11 may comprise a first metal portion 11A and a second metal portion 11B, and the first metal portion 11A and the second metal portion 11B may be electrically connected to the conductive layer 15 respectively. More specifically, the conductive layer 15 may comprise three separate parts, such as a conductive part 15A, a conductive part 15B and a conductive part 15C. The conductive part 15A may be electrically connected to the first metal portion 11A through the opening H of the insulating layer (for example, the opening H1 of the first insulating layer 12 and the opening H2 of the second insulating layer 14). The conductive part 15B may be electrically connected to the first metal portion 11A and the second metal portion 11B respectively through the opening H of the insulating layer (for example, the opening H1 of the first insulating layer 12 and the opening H2 of the second insulating layer 14). The conductive part 15C may be electrically connected to the second metal portion 11B through the opening H of the insulating layer (for example, the opening H1 of the first insulating layer 12 and the opening H2 of the second insulating layer 14). Thus, when performing an electrostatic discharge test on the electronic device, the current will be transmitted from the conductive part 15C to the conductive part 15B through the second metal portion 11B, and then transmitted from the conductive part 15B to the conductive part 15A through the first metal portion 11A, and finally enter the work area AA (as shown in FIG. 1A) of the electronic device through the test terminal T to perform the electrostatic discharge test.

In the present disclosure, as shown in FIG. 4A to FIG. 4C, the electrostatic protection structure S takes the first metal layer 11 as an example; but the present disclosure is not limited thereto. In other embodiments of the present disclosure, even not shown in the figure, the first metal layer 11 of the electrostatic protection structure S may be replaced by the second metal layer 13 (for example, as shown in FIG. 2B). More specifically, the second metal layer 13 (for example, as shown in FIG. 2B) may comprise two separate parts to replace the first metal portion 11A and the second metal portion 11B of the first metal layer 11 shown in FIG. 4A to FIG. 4C to electrically connect to the conductive part 15A, the conductive part 15B and the conductive part 15C, allowing the current to be transmitted to work area AA (as shown in FIG. 1A) for electrostatic discharge test.

In one embodiment of the present invention, as shown in FIG. 4A and FIG. 4D, the conductive part 15B may comprise a first portion 15B1 and a second portion 15B2, and the first portion 15B1 is connected to the second portion 15B2. In the top view direction Z, the width W1 of the first portion 15B1 is different from the width W2 of the second portion 15B2. By designing the width W1 of the first portion 15B1 different from the width W2 of the second portion 15B2, when the current passes through, a difference in resistance value will occur; and if the current passing through is too large, the conductive part 15B will be easily damaged or broken. Therefore, it is possible to prevent the current from directly impacting the electronic components in the work area AA (as shown in FIG. 1A), thereby reducing the risk of electronic device damage. In the present disclosure, there is a difference DV between the width W1 of the first portion 15B1 and the width W2 of the second portion 15B2, and the difference DV is greater than or equal to 1 μm and less than or equal to 100 μm (1 μm≤DV=|W1−W2|≤100 μm). In other words, the difference DV between the width W1 of the first portion 15B1 and the width W2 of the second portion 15B2 may range from 1 μm to 100 μm, for example, from 3 μm to 100 μm, 5 μm to 100 μm, 10 μm to 100 μm or 10 μm to 80 μm; but the present disclosure is not limited thereto. Here, the “width” refers to the maximum size of the component in a direction (for example, the X direction) perpendicular to the normal direction of the substrate 1 (for example, the Z direction).

In one embodiment of the present invention, as shown in FIG. 4A and FIG. 4D, the conductive part 15B may comprise a plurality of first portions 15B1 and a plurality of second portions 15B2, the first portions 15B1 and the second portions 15B2 are connected to each other and alternately disposed, and the widths W1 of the first portions 15B1 are different from the widths W2 of the second portions 15B2. By continuously setting plural first portions 15B1 and second portions 15B2 with different widths, the effect of the electrostatic protection structure can be improved.

In the present disclosure, other details of the test terminal T may be as described above, and are not described again here. In addition, the materials and the manufacturing processes of the first metal layer 11, the second metal layer 13, the first insulating layer 12, the second insulating layer 14 and the conductive layer 15 may be as described, and are not described here again.

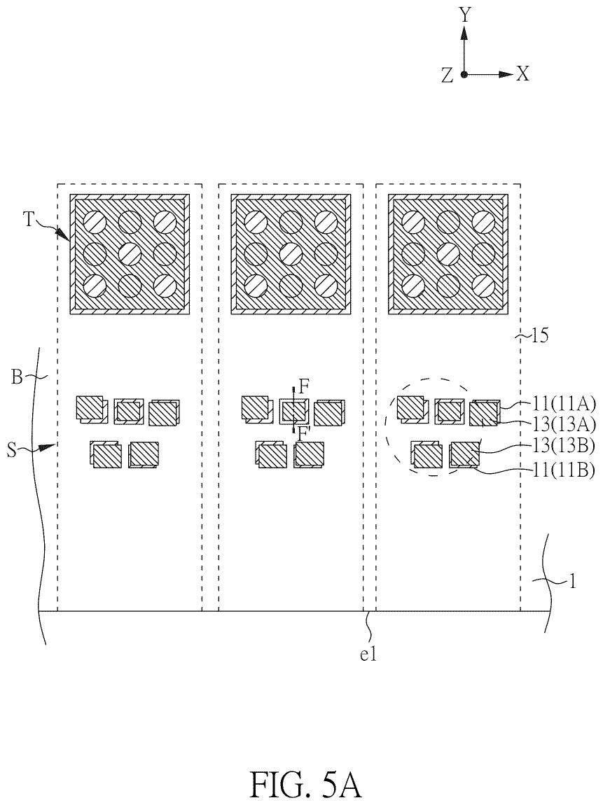

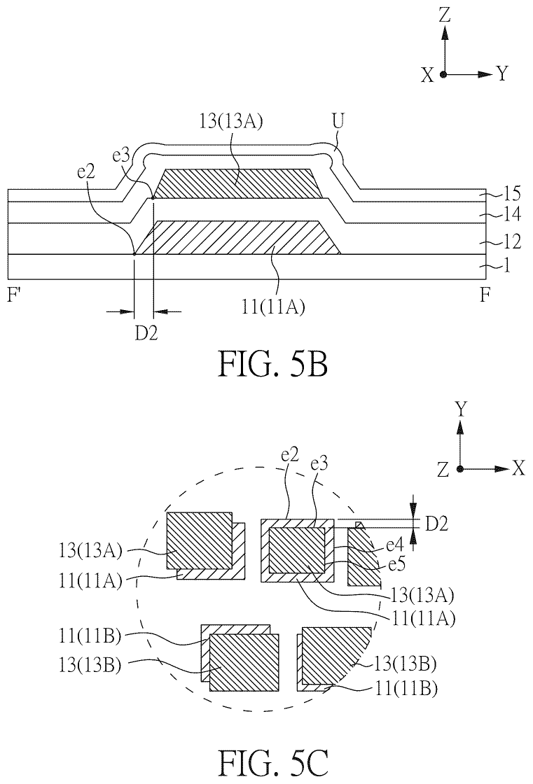

FIG. 5A is a top schematic diagram of a part of an electronic device according to one embodiment of the present invention. FIG. 5B is a cross-sectional schematic diagram of FIG. 5A along the line F-F′. FIG. 5C is an enlarged view of the dash line portion of FIG. 5A. For convenience of explanation, some components are omitted in FIG. 5A and FIG. 5C.

In one embodiment of the present invention, as shown in FIG. 5A, the electronic device may comprise: a test terminal T disposed on the peripheral area B; and an electrostatic protection structure S disposed on the peripheral area B. In the top view direction Z of the electronic device, the electrostatic protection structure S is located between the test terminal T and the edge e1 of the substrate 1. In the present disclosure, the test terminal T in FIG. 5A is the same as the test terminal T in FIG. 2A, so the cross-section of the test terminal T in FIG. 5A may be as shown in FIG. 2B and is not described again here.

In one embodiment of the present invention, as shown in FIG. 5A and FIG. 5B, the electrostatic protection structure S may comprise: a first metal layer 11 disposed on the substrate 1; a first insulating layer 12 disposed on the first metal layer 11; a second metal layer 13 disposed on the first insulating layer 12; a second insulating layer 14 disposed on the second metal layer 13; and a conductive layer 15 disposed on the second insulating layer 14, wherein the conductive layer 15 is electrically insulated from the first metal layer 11 and the second metal layer 13, and the conductive layer 15 is electrically connected to the test terminal T.

In one embodiment of the present invention, as shown in FIG. 5B and FIG. 5C, in the top view direction Z of the electronic device, there is a second distance D2 between the edge e2 of the first metal layer 11 and the edge e3 of the second metal layer 13, and the second distance D2 may range from 0 μm to 5 μm (0 μm≤D2≤5 μm), for example, may range from 0 μm to 3 μm or from 0 μm to 1 μm; but the present disclosure is not limited thereto. In one embodiment of the present invention, as shown in FIG. 5B, in a direction (for example, the Y direction) perpendicular to the normal direction of the substrate 1 (for example, the Z direction), there is a second distance D2 between the edge e2 of the first metal layer 11 and the edge e3 of the second metal layer 13, and the second distance D2 may range from 0 μm to 3 μm, for example, may range from 0 μm to 2 μm or 0 μm to 1 μm; but the present disclosure is not limited thereto. When the second distance D2 meets the aforesaid range, the outline of the conductive layer 15 in the electrostatic protection structure S will have an uneven structure U, as shown in FIG. 5B. When the passing current is too large, the conductive layer 15 is easily damaged or broken at the uneven structure U, so it is possible to prevent the current from directly impacting the electronic components in the work area AA (as shown in FIG. 1A), thereby reducing the risk of the electronic device damage. The “uneven structure” may be, for example, protrusions, concaves, rough surfaces or a combination thereof.

In the present disclosure, as shown in FIG. 5B and FIG. 5C, the second distance D2 refers to, for example, the distance between the edge e2 of the first metal layer 11 and the edge e3 of the second metal layer 13 along the Y direction; but the present disclosure is not limited thereto. In other embodiments of the present disclosure, the second distance D2 may also refer to the distance between another edge e4 of the first metal layer 11 and another edge e5 of the second metal layer 13 along the X direction. Thus, in the present disclosure, the second distance D2 may be the distance between one edge of the first metal layer 11 and one edge of the second metal layer 13 along the direction (for example the X direction or the Y direction) perpendicular to the normal direction of the substrate 1 (for example, the Z direction).

In one embodiment of the present invention, as shown in FIG. 5A, the first metal layer 11 of the electrostatic protection structure S may comprise a plurality of first metal portions 11A and a plurality of second metal portions 11B, the second metal layer 13 of the electrostatic protection structure S may comprise a plurality of third metal portions 13A and a plurality of fourth metal portions 13B, the third metal portions 13A are respectively disposed on the first metal portions 11A, and the fourth metal portions 13B are respectively disposed on the second metal portions 11B. In the direction perpendicular to the top view direction Z of the electronic device (for example, the Y direction), one of the first metal portions 11A may be partially overlapped with one of the second metal portions 11B. By the above design, when the passing current is too large, it is possible to prevent the current from directly impacting the electronic components in the work area AA (as shown in FIG. 1A), thereby reducing the risk of damage to the electronic device.

In the present disclosure, the details of the test terminal T may be as described above and are not described again here. In addition, the materials and the manufacturing processes of the first metal layer 11, the second metal layer 13, the first insulating layer 12, the second insulating layer 14 and the conductive layer 15 may also as described above and are not described again here.

The above specific embodiments are to be construed as illustrative only and not in any way limiting of the remainder of the present disclosure.

Although the present disclosure has been explained in relation to its embodiment, it is to be understood that many other possible modifications and variations can be made without departing from the spirit and scope of the disclosure as hereinafter claimed.

1. An electronic device, comprising:
a substrate comprising a work area and a peripheral area, wherein the peripheral area surrounds the work area;
a test terminal disposed on the peripheral area; and
an electrostatic protection structure disposed on the peripheral area,
wherein the electrostatic protection structure is located between the test terminal and an edge of the substrate in a top view direction.

2. The electronic device of claim 1, wherein the electrostatic protection structure is electrically connected to the test terminal.

3. The electronic device of claim 1, wherein the electrostatic protection structure comprises:
a first metal layer disposed on the substrate;
a first insulating layer disposed on the first metal layer; and
a conductive layer disposed on the first insulating layer.

4. The electronic device of claim 3, wherein the conductive layer is electrically connected to the first metal layer, and the conductive layer is electrically connected to the test terminal.

5. The electronic device of claim 3, wherein the first metal layer comprises a first metal portion and a second metal portion, the first metal portion is electrically connected to the conductive layer, and the second metal portion is electrically insulated from the conductive layer.

6. The electronic device of claim 5, wherein in the top view direction, the first metal portion comprises a first tip, the second metal portion comprises a second tip, and the first tip is disposed opposite to the second tip.

7. The electronic device of claim 6, wherein there is a first distance between the first tip and the second tip, and the first distance is greater than or equal to 2 μm and less than or equal to 10000 μm.

8. The electronic device of claim 6, wherein the electrostatic protection structure further comprises a second metal layer disposed on the first insulating layer, and the second metal layer comprises a third tip disposed opposite to the first tip.

9. The electronic device of claim 3, wherein the conductive layer comprises a first portion and a second portion, the first portion is connected to the second portion, and a width of the first portion is different from a width of the second portion in the top view direction.

10. The electronic device of claim 9, wherein there is a difference between the width of the first portion and the width of the second portion in a normal direction perpendicular to the substrate, and the difference is greater than or equal to 1 μm and less than or equal to 100 μm.

11. The electronic device of claim 3, wherein the electrostatic protection structure comprises a second metal layer disposed on the first insulating layer, there is a second distance between an edge of the first metal layer and an edge of the second metal layer in the top view direction, and the second distance is between 0 μm and 5 μm.

12. The electronic device of claim 1, wherein the test terminal comprises:
a first metal layer disposed on the substrate;
a first insulating layer disposed on the first metal layer;
a second metal layer disposed on the first insulating layer;
a second insulating layer disposed on the second metal layer; and
a conductive layer disposed on the second insulating layer,
wherein the conductive layer is electrically connected to the first metal layer and the second metal layer.

13. The electronic device of claim 12, wherein the conductive layer is electrically connected to the first metal layer through an opening of the first insulating layer, and the conductive layer is electrically connected to the second metal layer through an opening of the second insulating layer.

14. The electronic device of claim 1, wherein the electrostatic protection structure comprises a first portion and a second portion, wherein the second portion is located between the first portion and the edge of the substrate in the top view direction.

15. The electronic device of claim 14, wherein the first portion of the electrostatic protection structure comprises:
a first metal layer disposed on the substrate;
a first insulating layer disposed on the first metal layer;
a second insulating layer disposed on the first insulating layer; and
a conductive layer disposed on the first insulating layer and the second insulating layer,
wherein the conductive layer is electrically connected to the first metal layer, and the conductive layer is electrically connected to the test terminal.

16. The electronic device of claim 15, wherein the second portion of the electrostatic protection structure comprises:
the first metal layer disposed on the substrate;
the first insulating layer disposed on the first metal layer;
a second metal layer disposed on the first insulating layer;
the second insulating layer disposed on the second metal layer; and
the conductive layer disposed on the first insulating layer and the second insulating layer,
wherein the conductive layer is electrically connected to the first portion of the electrostatic protection structure.

17. The electronic device of claim 3, wherein the first metal layer comprises a first metal portion and a second metal portion, the first metal portion and the second metal portion are electrically connected to the conductive layer respectively.

18. The electronic device of claim 17, wherein the conductive layer comprises a conductive part electrically connected to the first metal portion, and another conductive part electrically connected to the first metal portion and the second metal portion.

19. The electronic device of claim 18, wherein the conductive layer further comprises a further another conductive part electrically connected to the second metal portion.

20. The electronic device of claim 18, wherein the another conductive part comprises a first portion and a second portion, the first portion is connected to the second portion, and a width of the first portion is different from a width of the second portion in the top view direction.
